(19) United States
(12) Patent Application Publication
(10) Pub. No.: US 2010/0270147 A1
(43) Pub. Date: Oct. 28, 2010

(54) Transportable, miniature, chamberless, low power, micro metallizer

(76) Inventor: Nigel Williams, (US)

Correspondence Address: EZRA SUTTON & ASSOCIATES, P.A., SUITE 201, 900 ROUTE 9 NORTH, WOODBRIDGE, NJ, 07095, US

(21) Appl. No.: 12/386,891

(22) Filed: Apr. 27, 2009

(51) Int. Cl. C23C 14/35

(52) U.S. Cl. 204/298.16

(57) ABSTRACT

The present invention provides a portable, compact, metallizer for metallizing an article with a coating of metal. The metallizer includes a circular transport member having a plurality of cavities each for receiving an object to be metallized; wherein each cavity and object passes through a loading station and a metallization station. The transport member moves each of the cavities to a loading station for receiving the object and then to a metallization station for metallizing the object. Vacuum means are provided for creating a partial vacuum in one of the cavities at the loading station. A metallization unit is disposed at the metallization station having a magnetron for creating an electromagnetic field for energizing a source of gas. A source of metal is impacted by the energized gas to metallize the object in one of the cavities. A turbo pump is provided for creating a high vacuum in one of the cavities when it is at the metallization station.

### FIELD OF THE INVENTION

The present invention relates to a new light weight and portable metallizer for coating metal on plastic substrates, as well as other substrates. The purpose of this metallizer is to provide Law Enforcement a machine and process to issue security documents that are immune from copying and duplication while in the field.

This is achieved by utilizing a low level of vacuum that is constantly maintained at loading and unloading stations, while a high level of vacuum is created at a miniature metallizing station each time a new object is at the station. In this manner, the invention provides for a portable, miniature, low power, and light weight metallizer for use in the field.

### BACKGROUND OF THE INVENTION

Sputtering and vacuum deposition of metal as means of coating are well-established processes, and the depositions machines are well known. The common characteristics of these machines are that they consume a lot of energy, they are very large, they use running water for cooling, and they are very heavy in weight. Therefore, it was never before possible to transport such a machine to an area that suffered a severe natural disaster or after a major terror attack, where such a machine is actually needed, but because of power requirements, size and weight it could provide this as an “on site” service.

In a CD metallization machine, after a CD is injection molded, it has to be metallized, coated, printed with certain information, and protected. The most critical aspect of the process is coating the metal over one of the CD plastic surfaces. Normally, the CDs are sequentially treated in a rotary movement and the lid must be open first for the insertion of each CD, and then re open again to extract the metallized CD from the vacuum chamber.

Every time the lid is opened, ambient air enters the cavity, and before the metallization step, all the ambient air must be extracted completely in order to create a high vacuum level. The vacuum level should be between 5.4 power of 10 X-3 Milibar to 3 power 10 X-3 Milibar. Following the extraction of the metallized CD, and the insertion of a new one, the vacuum level must be re instated to the high operational level within one or two seconds. Reaching this level of vacuum in such a short time, consumes a lot of energy. Constructing a machine with vacuum pumps with the power capacity and size required, mandates a large machine and such a machine consumes a lot of energy. This requires a large electric company connection, and a way to cool the machine. Normally, a supply of more than 15 gallons per minutes of cool running water must be part of the process.

As a result, the current metallization machines are large, very heavy, absolutely stationary, bolted to a concrete floor, and must be supplied with 3 phase electrical power of more than 100 amps per phase. Also, a running water source and a drainage system are required.

### OBJECTS OF THE INVENTION

It is an object of the present invention to provide a portable, high-speed, small, portable, low power consumption metallizer that does not need a three phase power supply, is light weight, can operate off a vehicle's 12 volt power supply, and does not require cooling water.

It is an object of the present invention to provide a portable metallizer that places a very thin layer of metal anywhere on an object or a document, in a pre-designed shape, volume, and thickness.

One object of the present invention is to address a need to respond to a post terror or natural disaster event. The metallizer of this invention makes in the field, on line, a highly secure document completely immune from imitation, duplication, replication, or counterfeiting.

Another object of the present invention provides a secure document, which may be in the form of an ID data carrier, which contains a security device that is completely immune from copying, duplication, and counterfeiting.

It is another object of this invention to provide a portable, light weight, and small metallizer that can produce such an ID data carrier and image.

In the present invention, the metallizer coats metal over plastic in a portable, rapid, sequential and dry process which is very unique, and for certain applications it is essential.

It is an object of the present invention to provide a metallizer capable of providing a coating of metal over the image which prevents the image from being copied, imitated or replicated.

It is an object of the present invention to provide a portable metallizing machine that can be operated by power supplied from the 12 volt battery of a vehicle, or from its engine. Alternately, a small portable generator can be used.

The portable unit can fit comfortably, with the necessary ID printing equipment, inside a 4×4 van and produce the secure document and image on site in the field wherever it may be needed.

An object of the present invention is to avoid bringing into the metallization chamber ambient air which then has to be entirely evacuated and replaced with a new vacuum before the metallization process can take place.

It is an object of the present invention to keep a reduced vacuum throughout the process without losing it during the product exchange cycle.

Another object of the present invention is to provide a tightly sealed tubular rotating transport surface which is machined with great precision to form carrying cavities with very tight tolerances.

Another object of the invention is to eliminate the conventional vacuum chamber and replace it with a tiny milled cavity formed in the surface of the transport mechanism.

Another object is that the object to be metallized is placed inside a small cavity without having a vacuum chamber being “opened” or “closed” like all other sequential sputtering devices.

An object of the present invention is to provide a rotating circular transport platform with four carrying cavities which are exactly milled for the exact size of the intended object to be metallized.

Another object is to minimize the size and power consumption of the device by inserting and extracting the object from the metallizer without opening or closing any lid, which avoids losing the vacuum environment that takes a lot of energy to re instate.

### SUMMARY OF THE INVENTION

The present invention provides a portable, compact, metallizer for metallizing an article with a coating of metal. The metallizer includes a circular transport member having a plurality of cavities each for receiving an object to be metallized; wherein each cavity and object passes through a loading station and a metallization station. The transport member moves each of the cavities to a loading station for receiving the object and then to a metallization station for metallizing the object. Vacuum means are provided for creating a partial vacuum in one of the cavities at the loading station. A metallization unit is disposed at the metallization station having a magnetron for creating an electromagnetic field for energizing a source of gas. A source of metal is impacted by the energized gas to metallize the object in one of the cavities. A turbo pump is provided for creating a high vacuum in one of the cavities when it is at the metallization station.

### DESCRIPTION OF THE DRAWINGS

FIG. 1 shows circular ring 20 having four cavities passing through four stations 30, 34, 50, and 90;

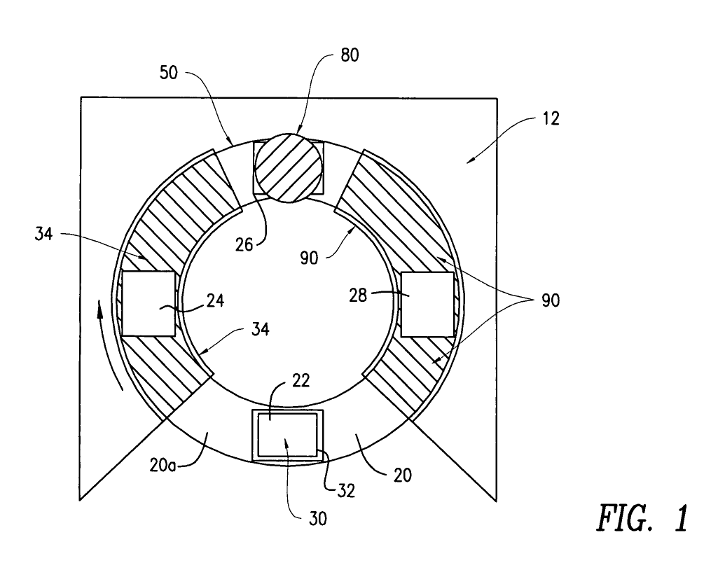

FIGS. 2A, 2B, and 2C show different views of station or zone 34 having a sealed passageway 14;

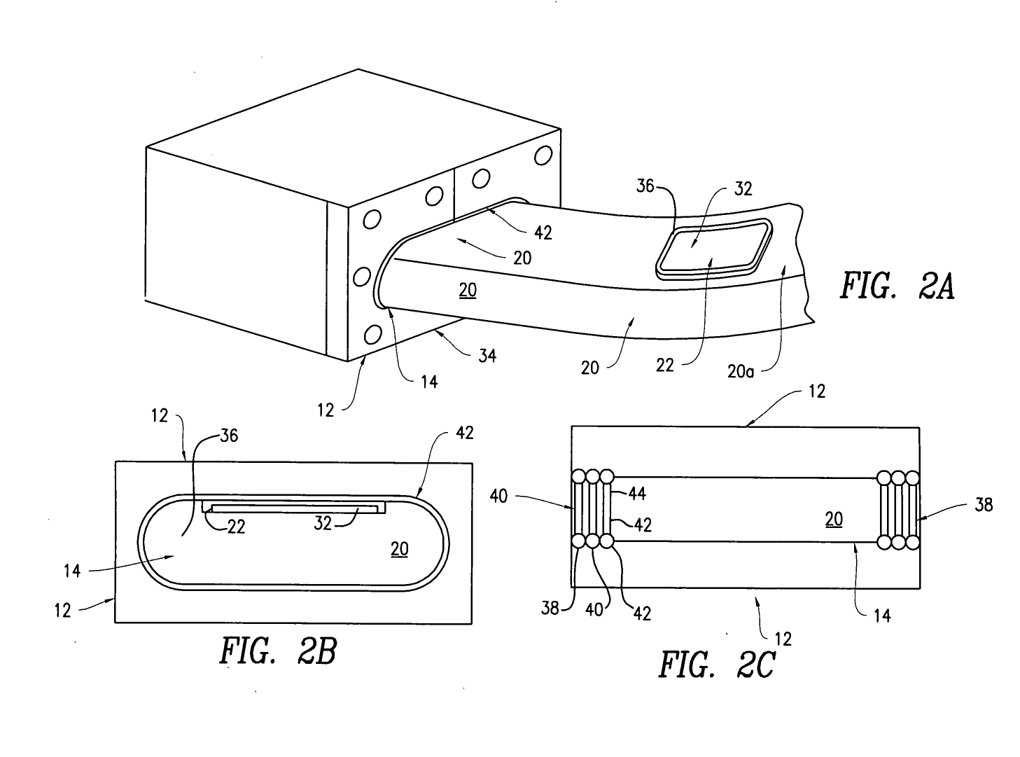

FIG. 3 shows a view of the passageway 14 at station 50 with the magnetron 100 above station 50 for performing metallization;

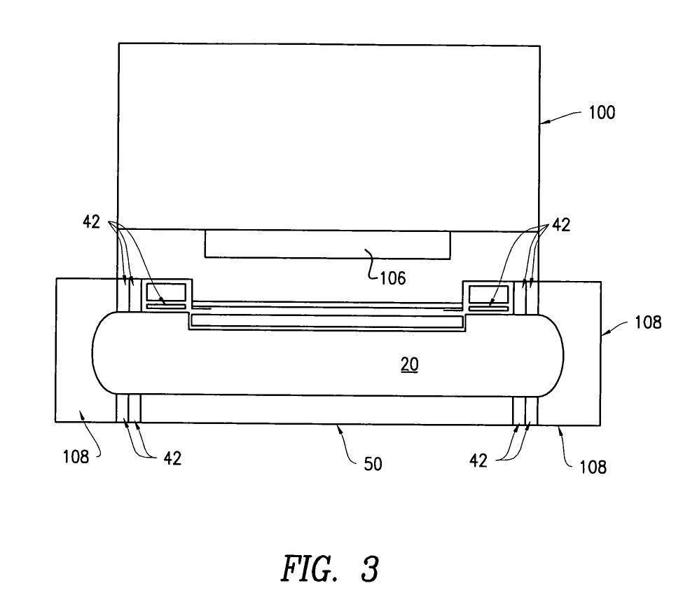

FIG. 4 shows the passageway 14 at station 50 with the magnetron 100 above station 50 for performing metallization;

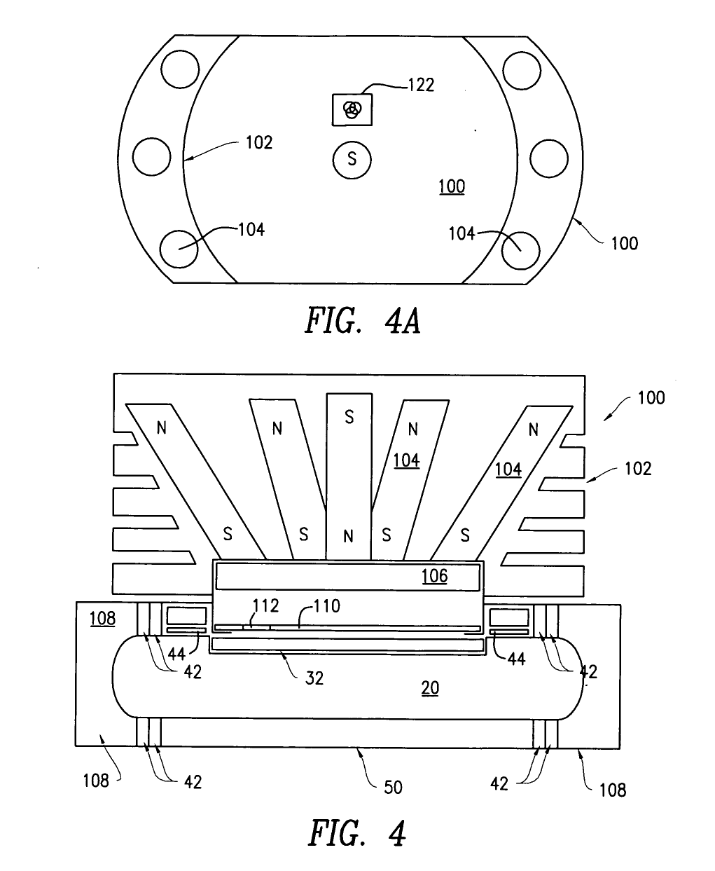

FIG. 5 shows details of the magnetron 100 and the metallization chamber below it;

FIG. 6 shows how the portable unit 10 is connected in the field; and

FIG. 7 shows the two pumping systems 48 and 120.

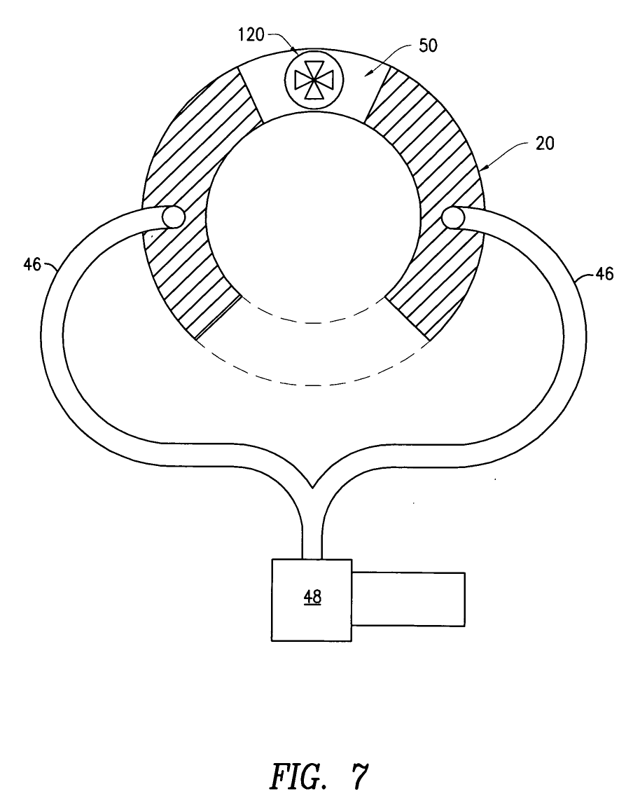

### DESCRIPTION OF THE PREFERRED EMBODIMENT

The following is a description of the preferred embodiment of the invention, which has four stations, which will be described first.

### Station One: Load Position

The rotating circular transport platform or carrier ring 20 has four spaced-apart carrying cavities 22, 24, 26, and 28 formed in its upper surface 20a. This station 30 is for loading the object 32 into one of the four carrying cavities that is at the loading station. At this loading station 30, the object 32 to be metalized is placed into the cavity 22. Ambient air is still surrounding the object.

### Station Two: Roughing Vacuum Zone

The cavity 22 holding the object 32 to be metallized, moves clockwise in direction to this next station 34, called the first vacuum inducing zone formed in the machine frame 12 having a passageway 14 through which the carrier ring 20 passes.

This is not a conventional vacuum chamber. Instead, it utilizes a sealed compartment 36 of the rotating circular platform 20, which is sealed on each side by triple parallel seals 38 and 40, each being comprised of three side by side flexible sealing rings 42 separated by two “PI” shaped, milled hard rings 44, causing the flexible and elastic material to tightly seal the compartment 36.

A metal pipe 46 connects compartment 36 directly to roughing pump 48, which extracts the air from this small sealed compartment 36 within the cavity 22, that exists between the rotating circular platform 20 and the encapsulating wall. In a matter of few seconds, the first vacuum inducing zone, which is the compartment 36 between the two triple seals 38 and 40, reaches the full vacuum capacity of the roughing pump 48. The effort required for the roughing pump 48 to establish this first level of operating vacuum is minimized by the absence of a traditional vacuum chamber having ambient air that must be rapidly extracted.

At this point, the object 32 in cavity 22 is ready to proceed with the rotation of transport platform 20 to move toward the third station 50, where object 32 is going to be metallized by a magnetron 100, as explained below.

### Station Three: High Vacuum Metallization Zone

At this station 50, actual metallization takes place under a high vacuum.

Similar to the roughing zone at station 34, this compartment is also bordered with a triple sealing system. A Turbo Vacuum Pump 120 is connected to this zone 50. Because the object 32 arrives at this station 50 when it is already under the roughing vacuum level, it makes it easier for the Turbo Pump 120 to maintain the higher vacuum level of 5.4 power of 10 X-3.

The cavity 22 carries the object 32 to this station 50 under the metallization head 80 and magnetron 100. There the transport platform 20 may be briefly stopped or it may move continuously while object 32 is being metallized. This is determined by the requirement of metal density and metal detection.

After the metallization process is completed at station 50, the object 32 continues its rotation clockwise to the second roughing zone at the fourth station 90.

### Station Four: Unload Position:

At this station 90, this zone is kept under vacuum (the same level as station 34), to ensure that the high vacuum area at station three is not bordering sections that are not under vacuum which would make it much harder to maintain the high vacuum.

At this station, the metallized object 32 is extracted from cavity 22 and a new object is placed in the cavity 22.

At the third station 50, there is a magnetron 100 that includes a magnet array 102 made up of a plurality of north-south magnets 104. Disposed below the magnet array is a target 106 consisting of metal to be used for the metallization process. Disposed below the target 106 is an insulation ring 108 having disposed therein a quick change mask 110 having a window 112 formed therein. In addition, an Argon mass flow control 116 is provided to supply Argon gas to the insulation ring 108. Below the insulation ring 108 is the turbo-molecular pump 120 for maintaining the high vacuum within the insulation ring 108 where the metallization step takes place. The DC power supply 122 having 500 volts energizes the magnets 104 to create an electro-magnetic field which energizes the Argon gas and causes the Argon molecules to hit the metal target 106, so that molecules of metal are removed from the target 106 and are deflected downwardly from the target 106 to the mask 110. Some of the metal is deposited on the object 32 contained within window 112 of mask 110, so that the object is metallized within the high vacuum. After the object 32 is metallized, it moves from station 50 to station 90 on the circular platform 20 to be unloaded at station 90.

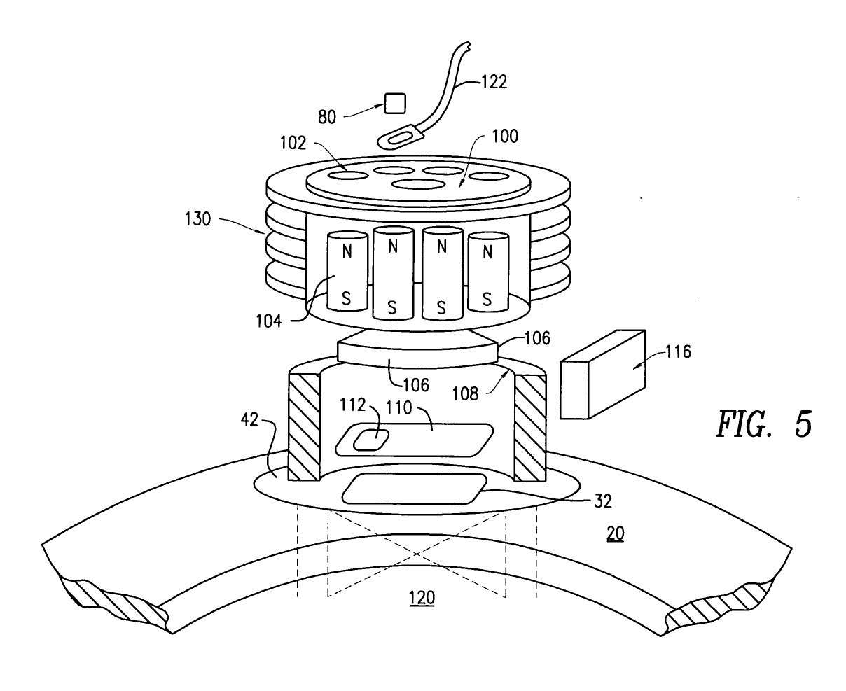

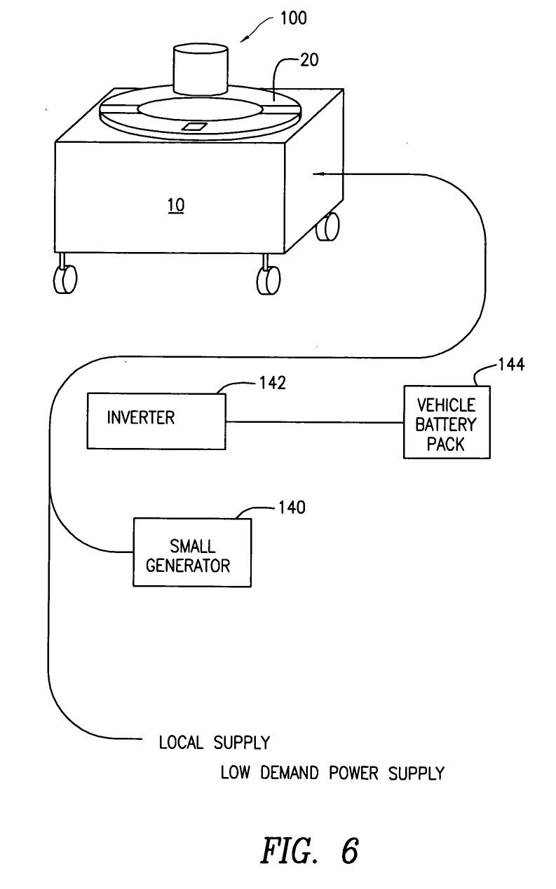

As shown in FIG. 6, the portable unit 10 is connected to an inverter 142, a battery pack 144 and a generator 140. As shown in FIG. 5, magnetron 100 is above station 50 for performing the metallization.

It should be understood that this invention may employ multiple magnetron heads, instead of a single magnetron head. Multiple heads will allow metallization of several metal layers being applied consecutively on the same object.

It should also be understood that this invention may be employed to metallize any article or object, and is not limited to metallizing data carriers.

### ADVANTAGES OF THE INVENTION

The first advantage of the invention is that it provides a small and portable Metallizer which is operational from a motor vehicle power source. This is achieved by reducing the pumped volume to an absolute minimum to quickly achieve a vacuum. This is further achieved by machining four precision cavities 20, 22, 24, and 26 into the top surface of the circular transport 20 so that when an object 32 is placed in the carrying cavity 22 virtually all the ambient is displaced leaving a microscopic amount for the roughing pump to extract to create a vacuum. Therefore a low energy vacuum pump 48 can be used at stations 34 and 90 to maintain the vacuum at these stations.

The second advantage of the invention is that it provides a long precision seal area which is constantly pumped at stations 34 and 90, (unlike a conventional load lock that has to achieve vacuum in a short space of time). This also allows a much smaller vacuum pump at stations 34 and 90, and is therefore more energy efficient.

The third advantage of the invention is that because the seals are dynamic and not static, the circular transport 20 can rotate while pumping is still effective. This means that the object 32 can be passed under the deposition head while it is operating. Therefore, the deposition head can be much smaller because it only has to deposit on a small area and the data carrier will pass through the deposition area. Because of the small the size of the deposition head, less power is needed, so it can be run from a very low power supply.

A latitude of modification, change and substitution is intended in the foregoing disclosure, and in some instances, some features of the invention will be employed without a corresponding use of other features. Accordingly, it is appropriate that the appended claims be construed broadly and in a manner consistent with the spirit and scope of the invention herein.

What is claimed is:

1) A portable, compact, metallization machine for metallizing an article with a coating of metal, comprising:
a) a circular transport member having a plurality of cavities each for receiving an object to be metallized; wherein each cavity passes through a loading station for receiving the object and a metallization station where the object is metallized;
b) said transport member being movable to move one of said cavities to a loading station for receiving the object and then to a metallization station for metallizing the object;
c) vacuum means for creating a partial vacuum in one of said cavities at said loading station;
d) a metallization unit disposed at said metallization station having a magnetron for creating an electromagnetic field for energizing a source of gas; and a source of metal impacted by the energized gas to metallize the object in one of said cavities; and
e) means for creating a high vacuum in one of said cavities when it is at said metallization station.

2) A portable, compact, metallization machine for metallizing an article with a coating of metal, wherein the machine operates without a conventional vacuum chamber and without a conventional “loadlock,” comprising:
a) a circular transport member having a plurality of cavities each for receiving an object to be metallized; wherein each cavity passes through a loading station and a metallization station;
b) said transport member being movable to move one of said cavities to a loading station for receiving the object and then to a metallization station for metallizing the object;
c) vacuum means for creating a partial vacuum in one of said cavities at said loading station;
d) a metallization unit disposed at said metallization station having a magnetron for creating an electromagnetic field for energizing a source of gas; and a source of metal impacted by the energized gas to metallize the object in one of said cavities; and
e) means for creating a high vacuum in one of said cavities when it is at said metallization station.
